(19) United States
(12) Patent Application Publication
(10) Pub. No.: US 2003/0117124 A1
(43) Pub. Date: Jun. 26, 2003

(54) Digital clock detection

(76) Inventors: Stephen Paul Andrew, Tavistock (GB); Jonathan Francis Evered, Plymouth (GB)

Correspondence Address: THOMPSON HINE L.L.P., 2000 COURTHOUSE PLAZA , N.E., 10 WEST SECOND STREET, DAYTON, OH, 45402, US

(21) Appl. No.: 10/286,276

(22) Filed: Nov. 1, 2002

(30) Foreign Application Priority Data
Nov. 2, 2001 (GB) 0126357.3

(51) Int. Cl. G01R 13/02

(52) U.S. Cl. 324/76.82

(57) ABSTRACT

A digital clock detector for detecting whether a digital clock, for providing an output alternating between a high value and a low value, is running or stopped, comprises:

two or more digital delay gates connected to said clock, said delay gates being connected in a chain; and

logic circuitry arranged to determine whether the logic levels on either side of each of said gates are the same or different, and to thereby provide an output which indicates whether said digital clock is running, or whether said digital clock has stopped while providing an output which corresponds to either said high value or said low value.

### TECHNICAL FIELD

The invention relates to the detection of digital clock signals in a digital circuit.

### BACKGROUND

Historically, at a board level implementation, the detection of a clock signal would be done using analogue components in a timer, monostable or similar configuration, e.g. the classic 555 timer. At the chip level, the use of analogue libraries is made in CMOS integrated circuit design for modules such as phase locked loops and other analogue functions, but use of such libraries may be undesirable for certain applications. This may be the case if, for example, analogue components cannot be simulated using digital simulators, or if no analogue library is available for the chosen technology, or for cost or other reasons.

### SUMMARY

According to the invention there is provided a digital clock detector and a method as set out in the accompanying claims U.S. Pat. No. 4,113,493 to Sandhu et al. discloses specific heat activatable adhesive compositions for use in radiation-sensitive elements and particularly photographic elements. The heat-activatable solvent-soluble adhesive compositions are capable of binding hydrophilic surfaces to hydrophobic surfaces in photographic materials. Adhesives are described as being useful in bonding photosensitive layers to image-receiving layers, subbing layers to supports or cover sheets, etc. See column 2, lines 63-68. In general, the adhesives are useful to bond any layer to another, but particularly polymeric layers to other polymeric layers. The reference broadly discloses that the adhesives can be used in silver halide radiation sensitive materials as well as nonsilver halide radiation sensitive materials, such as mechanical image materials, photoresists, electrophotographic image materials and thermal image materials. However, the reference fails to specifically disclose the use of the thermal activated adhesives with a photosensitive microcapsule system similar to the Cycolor photographic coating.

### BRIEF DESCRIPTION OF DRAWINGS

An embodiment of the invention will now be described, by way of example only, with reference to the accompanying drawings, in which:

FIG. 1 shows a digital clock detector, in accordance with an embodiment of the invention; and

FIG. 2 shows a timing diagram illustrating the propagation of a clock signal through delay gates of the detector.

### DETAILED DESCRIPTION

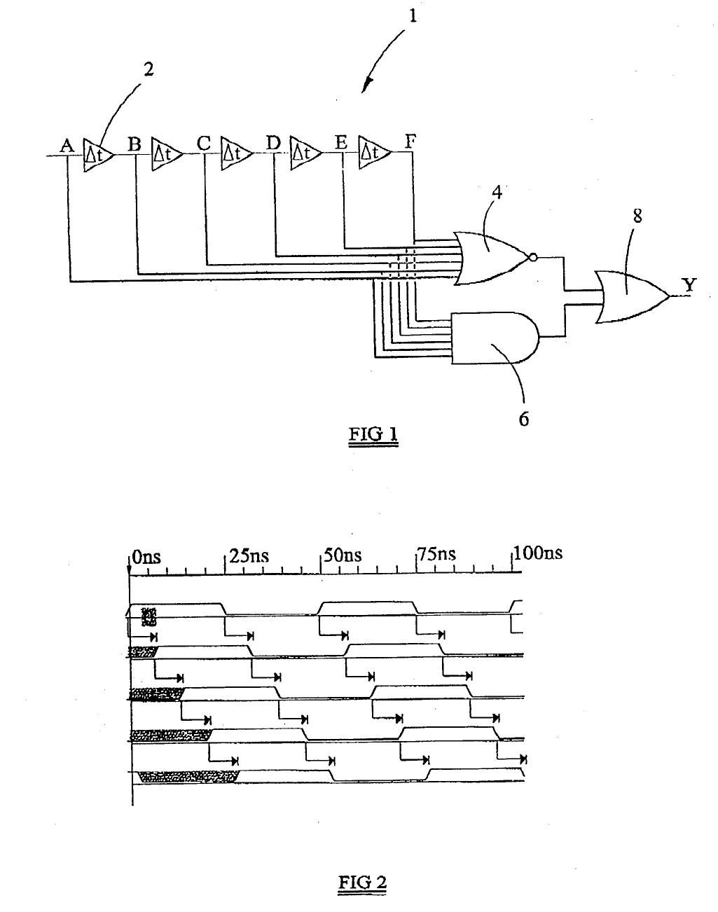

FIG. 1 shows a digital clock detector 1, which comprises a chain of digital delay gates 2 connected to a clock source (not shown). By delaying the clock transitions through the gates 2, it is possible to examine the state between each delay gate 2, and establish whether or not the clock is still toggling. The arrangement of delay gates 2 is as shown in FIG. 1.

The inputs and outputs of the delay gates 2 are connected to a logical NOR gate 4 and a logical AND gate 6, as shown in FIG. 1. The outputs of the gates 4 and 6 are connected to a logical OR gate 8.

The digital clock detector circuit 1 makes use of only digital components.

When the required number of delay gates 2 is used, performing a logical-AND and a logical-NOR of each tap in the delay chain and finally a further logical-OR on the result provides a signal which indicates the ‘running’/‘stopped’ condition of the clock.

If the clock stops then each stage between successive delay gates 2 settles to the same logic level, either all high or all low. If the clock is running, provided that suitable delays and a suitable number of delay stages are used, then at least one of the stages between successive gates 2 will be different from the others. The resultant signal (Y) will yield a low (0) if the clock is running, and a high (1) if the clock has stopped. This is illustrated in Table 1 below.

TABLE 1
Illustration of clock condition

| A | B | . . . | F | Y | Clock condition |
|---|---|---|---|---|---|
| 0 | 0 | . . . | 0 | 1 | Stopped |
| 0 | 0 | . . . | 1 | 0 | Running |
| 0 | 1 | . . . | 0 | 0 | Running |
| 0 | 1 | . . . | 1 | 0 | Running |
| 1 | 0 | . . . | 0 | 0 | Running |
| 1 | 0 | . . . | 1 | 0 | Running |
| 1 | 1 | . . . | 0 | 0 | Running |
| 1 | 1 | . . . | 1 | 1 | Stopped |

The number of delay gates required, n, is dependent on the performance of the gates and the frequency of the clock signal. A calculation is required to determine n, it being a function of the delay range for the delay gate in question. The delay of a particular gate will have a minimum delay and a maximum delay specification. Thus the delay of the physical gate will be expected to sit within this range and will be governed by such factors as parasitic loading on the gate and its specific operating temperature, operating voltage and silicon processing variances during manufacture. Since these factors cannot be quantified at the time of design a number of gates must be used. This number allows for the delay to be anywhere within the range, tₛₕₒᵣₜ to t_{long}. If a sufficient number of delay gates is not used, then a condition may arise whereby the digital clock detector circuit indicates that the clock has stopped, when it is actually still running. The effect of using too many delay gates is that the clock stopped condition may be indicated a little later in time than would be possible by using the optimum number of gates. Also, using more gates than required is undesirable since it wastes space on silicon.

FIG. 2 is a timing diagram showing a clock signal, and how it may look as it propagates through the series of delay gates. The diagram illustrates the requirement for the sum of the propagation delays through the gates to be more than a half-cycle of the clock. We can see by the shaded area that it is only when the fifth delay (at the bottom of the figure) is added, that the accumulated delay is greater than half a cycle of the original clock signal. If the fifth gate had not been added in this example, then there is a period of time every clock cycle when the result of an exclusive or operation on all the delay stages would falsely indicate that the clock had stopped. The diagram shows that it is a requirement for the accumulative delay to be greater than half a cycle of the original clock signal.

The delay range of the delay gate is important. Some delay gates may not be suitable for detecting a certain clock. If the range between tₛₕₒᵣₜ and t_{long} encompasses the half period (T/2) of the clock to be detected (i.e. tₛₕₒᵣₜ≦T/2≦t_{long}), the delay chain cannot be guaranteed to work. This is because it is feasible that the delay gates may delay the clock for exactly half the clock period. In this case the circuit would falsely detect a stopped clock. In order to be guaranteed to operate properly, t_{long} must be shorter than a half clock cycle, or tₛₕₒₜ must be longer than a half clock cycle. Also the accumulative delay through the chain must be greater than a half cycle of the clock period, in the worst case of the delay gate range.

$$\begin{matrix}n \times {t}_{short} > \frac{T}{2} & Eqn 1 \\ n \times ( T - {t}_{long} ) > \frac{T}{2} & Eqn 2\end{matrix}$$

These requirements for functionality are summarised by the expressions shown below. The number of delay gates used (n) must satisfy both of equations (3) and (4) below.

$$\begin{matrix}n > ( \frac{T}{2 \times {t}_{short}} ) & Eqn 3 \\ n > ( \frac{T}{2 ( T - {t}_{long} )} ) & Eqn 4\end{matrix}$$

What is claimed is:

1. A digital clock detector for detecting whether a digital clock, for providing an output alternating between a high value and a low value, is running or stopped, the detector comprising:
two or more digital delay gates connected to said clock, said delay gates being connected in a chain; and
logic circuitry arranged to determine whether the logic levels on either side of each of said gates are the same or different, and to thereby provide an output which indicates whether said digital clock is running, or whether said digital clock has stopped while providing an output which corresponds to either said high value or said low value.

2. A detector as claimed in claim 1, wherein said logic circuitry comprises a logic AND gate and a logic NOR gate, and wherein the inputs and outputs of said delay gates are all connected to the inputs of both said logic AND gate and said logic NOR gate.

3. A detector as claimed in claim 2, wherein said logic circuitry further comprises a logic OR gate, and wherein the outputs of said logic AND and NOR gates are connected to the inputs of said logic OR gate.

4. A detector as claimed in claim 1, wherein said delay gates each provide a delay which varies between a minimum value of tₛₕₒᵣₜ, and a maximum value of t_{long}, wherein the period of the clock cycle is T, and wherein the number of delay gates n satisfies the following condition:
$$n > ( \frac{T}{2 \times {t}_{short}} )$$

5. A detector as claimed in claim 2, wherein said delay gates each provide a delay which varies between a minimum value of tₛₕₒᵣₜ, and a maximum value of t_{long}, wherein the period of the clock cycle is T, and wherein the number of delay gates n satisfies the following condition:
$$n > ( \frac{T}{2 \times {t}_{short}} )$$

6. A detector as claimed in claim 3, wherein said delay gates each provide a delay which varies between a minimum value of tₛₕₒᵣₜ, and a maximum value of t_{long}, wherein the period of the clock cycle is T, and wherein the number of delay gates n satisfies the following condition:
$$n > ( \frac{T}{2 \times {t}_{short}} )$$

7. A detector as claimed in claim 4, wherein the number of delay gates n also satisfies the following condition:
$$n > ( \frac{T}{2 ( T - {t}_{long} )} )$$

8. A detector as claimed in claim 5, wherein the number of delay gates n also satisfies the following condition:
$$n > ( \frac{T}{2 ( T - {t}_{long} )} )$$

9. A detector as claimed in claim 6, wherein the number of delay gates n also satisfies the following condition:
$$n > ( \frac{T}{2 ( T - {t}_{long} )} )$$

10. A detector as claimed in claim 4, wherein tₛₕₒᵣₜ>T/2, or t_{long}<T/2.

11. A detector as claimed in claim 6, wherein tₛₕₒᵣₜ>T/2, or t_{long}<T/2.

12. A detector as claimed in claim 7, wherein tₛₕₒᵣₜ>T/2, or t_{long}<T/2.

13. A detector as claimed in claim 9, wherein tₛₕₒᵣₜ>T/2, or t_{long}<T/2.

14. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value.

15. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value;
wherein the steps of the method are carried out by a detector as claimed in claim 1.

16. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value; wherein the steps of the method are carried out by a detector as claimed in claim 2.

17. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value; wherein the steps of the method are carried out by a detector as claimed in claim 3.

18. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value; wherein the steps of the method are carried out by a detector as claimed in claim 4.

19. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value; wherein the steps of the method are carried out by a detector as claimed in claim 7.

20. A method of detecting whether a digital clock, for providing an output alternating between a high value and a low value, is running or stopped, the method comprising:
delaying the digital clock signal by one or more multiples of a delay period, using one or more digital delay gates;
determining the logic level after each delay; and
determining whether said logic levels are the same or different, so as to thereby determine whether said digital clock is running, or whether said digital clock has stopped while providing an output which corresponds to either said high value or said low value; wherein the steps of the method are carried out by a detector as claimed in claim 10.
